(19) United States
(12) Patent Application Publication
(10) Pub. No.: US 2026/0280547 A1
(43) Pub. Date: Sep. 17, 2026

(54) SOFT STARTER AND SYSTEM MAINBOARD WITH SOFT-START FUNCTION

(71) Applicant: Alpha Networks Inc., Hsinchu (TW)

(72) Inventor: Kun-Neng CHUANG, Hsinchu (TW)

(21) Appl. No.: 19/279,218

(22) Filed: Jul. 24, 2025

(30) Foreign Application Priority Data
Mar. 14, 2025 (TW) 114109617

(51) Int. Cl. H03K 17/08

(52) U.S. Cl. CPC H03K 17/08

(57) ABSTRACT

A soft starter includes a switch and a switch-control circuit. The switch is connected between a power conversion circuit and an optical module. The switch operates in one of a closed state and an open state. The switch-control circuit has a first terminal connected to the optical module, and a control terminal connected to the switch. The switch-control circuit detects, via the first terminal, a connection signal that indicates whether the optical module is connected to the soft starter. Upon detecting the connection signal indicating that the optical module is connected to the soft starter, the switch-control circuit outputs, via the control terminal, a control signal to the switch after a period of latency to control the switch to switch from the open state to the closed state, such that the switch allows a driving current to flow through the switch to the optical module for starting the optical module.

### CROSS-REFERENCE TO RELATED APPLICATION

This application claims priority to Taiwanese Invention Patent Application No. 114109617, filed on Mar. 14, 2025, the entire disclosure of which is incorporated by reference herein.

### FIELD

The disclosure relates to a soft starter for an optical module, and a system mainboard with a soft-start function.

### BACKGROUND

Referring to FIG. 1, a conventional interface device for multiple optical modules 9 is illustrated. The conventional interface device includes a power conversion circuit 7 and multiple connection ports 8. When one of the optical modules 9 is connected to one of the connection ports 8, the power conversion circuit 7 would supply the one of the optical modules 9 with voltage power exemplarily of 3.3V.

However, upon one of the optical modules 9 being connected to one of the connection ports 8, an inrush current would arise and may cause damage to the one of the optical modules 9, thereby shortening service life of the one of the optical modules 9.

Besides, an unintended short circuit occurring within one of the optical modules 9 that is connected to one of the connection ports 8 may cause the one of the optical modules 9 to malfunction and to have extremely low impedance, further resulting in abnormalities in the conventional interface device. As a result, others of the optical modules 9 will not be able to normally utilize the conventional interface device at this time.

### SUMMARY

Therefore, an object of the disclosure is to provide a soft starter for an optical module and a system mainboard with a soft-start function that can alleviate at least one of the drawbacks of the prior art.

According to one aspect of the disclosure, the soft starter is adapted to be electrically connected between a power conversion circuit and the optical module so as to transmit a driving current outputted by the power conversion circuit to the optical module. The soft starter includes a switch and a switch-control circuit.

The switch is adapted to be electrically connected between the power conversion circuit and the optical module. The switch is configured to operate in one of a closed state for allowing the driving current to flow through the switch, and an open state for disallowing the driving current to flow through the switch.

The switch-control circuit has a first terminal that is adapted to be electrically connected to the optical module, and a control terminal that is electrically connected to the switch. The switch-control circuit is configured to detect, via the first terminal, a connection signal that indicates whether or not the optical module is electrically connected to the soft starter. The switch-control circuit is configured to, upon detecting the connection signal indicating that the optical module is electrically connected to the soft starter, output, via the control terminal, a control signal to the switch after a period of latency to control the switch to switch from the open state to the closed state, such that the switch allows the driving current to flow through the switch to the optical module for starting the optical module.

According to another aspect of the disclosure, the system mainboard is adapted to be electrically connected to at least one optical module. The system mainboard includes a plurality of ports each being configured to allow one of said at least one optical module to insert thereinto. The system mainboard further includes a plurality of the soft starters that are previously described and that are respectively disposed in the plurality of ports. The system mainboard further includes a power conversion circuit that is electrically connected to said plurality of the soft starters, and that is configured to, when one of said at least one optical module is inserted into one of said plurality of ports and is electrically connected to the corresponding one of said plurality of the soft starters, output a driving current to said one of said at least one optical module.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a block diagram illustrating a conventional interface device for multiple optical modules.

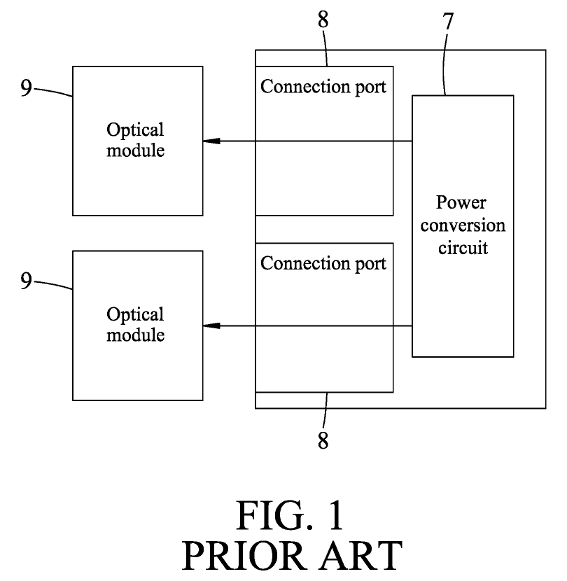

FIG. 2 is a block diagram illustrating a system mainboard according to an embodiment of the disclosure.

FIG. 3 is a block diagram illustrating a soft starter according to an embodiment of the disclosure.

FIG. 4 is a circuit diagram illustrating the soft starter according to an embodiment of the disclosure.

FIG. 5 is a schematic diagram illustrating a detecting circuit according to an embodiment of the disclosure.

FIG. 6 is a circuit diagram illustrating a switch-control circuit according to one embodiment of the disclosure.

FIG. 7 is a circuit diagram illustrating the switch-control circuit according to another embodiment of the disclosure.

FIG. 8 is a circuit diagram illustrating the switch-control circuit according to still another embodiment of the disclosure.

FIG. 9 is a circuit diagram illustrating the switch-control circuit according to further another embodiment of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

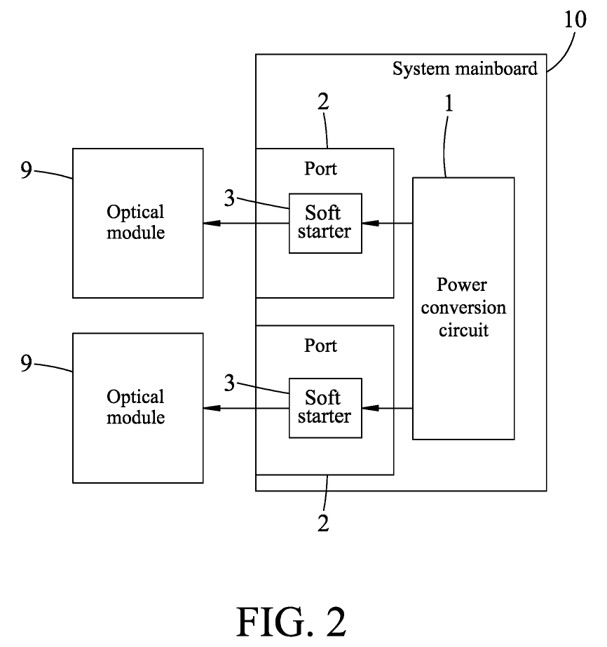

Referring to FIG. 2, an embodiment of a system mainboard 10 with a soft-start function according to the disclosure is illustrated. The system mainboard 10 is adapted to be electrically connected to at least one optical module 9. In this embodiment, said at least one optical module 9 includes multiple optical modules 9. The system mainboard 10 includes a power conversion circuit 1, a plurality of ports 2, and a plurality of soft starters 3 respectively disposed in the plurality of ports 2. The power conversion circuit 1 is electrically connected to the soft starters 3. Each of the soft starters 3 is adapted to be electrically connected between the power conversion circuit 1 and one of the optical modules 9.

Each of the ports 2 is configured to allow one of the optical modules 9 to insert thereinto. When one of the optical modules 9 inserts into one of the ports 2, the one of the ports 2 is configured to communicate with the one of the optical modules 9 through Inter-Integrated Circuit (I²C) bus, and to obtain, by utilizing a digital diagnostic monitoring (DDM) function, specification information about the one of the optical modules 9. The specification information contains data relevant to an operating temperature and a power level of the one of the optical modules 9.

The power conversion circuit 1 is configured to, when one of the optical modules 9 is inserted into one of the ports 2 and is electrically connected to the corresponding one of the soft starters 3, output a driving current to the corresponding one of the soft starters 3 to enable the corresponding one of the soft starters 3 to transmit the driving current to the one of the optical modules 9.

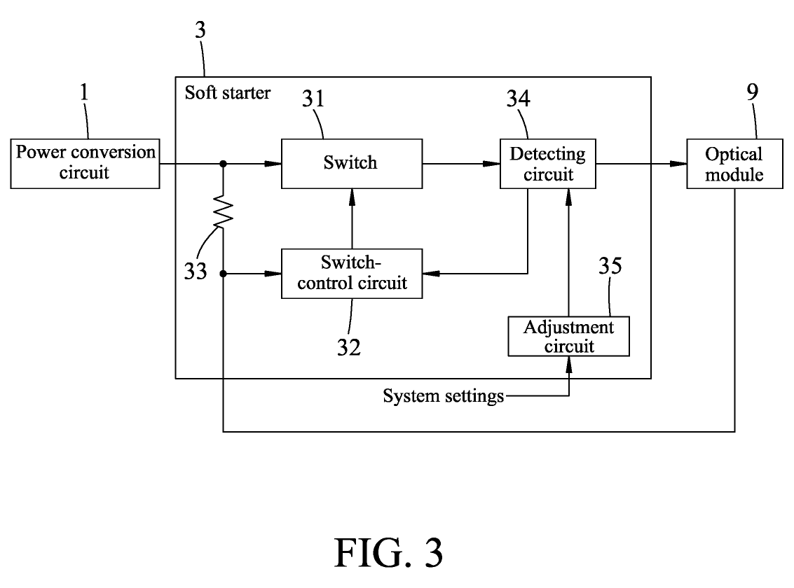

Referring to FIG. 3, each of the soft starters 3 includes a switch 31, a switch-control circuit 32, a pull-up resistor 33, a detecting circuit 34 and an adjustment circuit 35.

The switch 31 is adapted to be electrically connected between the power conversion circuit 1 and one of the optical modules 9. The switch 31 is configured to operate in one of a closed state for allowing the driving current to flow through the switch 31, and an open state for disallowing the driving current to flow through the switch 31.

The switch-control circuit 32 has a first terminal that is adapted to be electrically connected to one of the optical modules 9, a control terminal that is electrically connected to the switch 31, and a second terminal that is electrically connected to the detecting circuit 34. The switch-control circuit 32 is configured to detect, via the first terminal, a connection signal that indicates whether or not any one of the optical modules 9 is electrically connected to the soft starter 3. Upon detecting the connection signal indicating that one of the optical modules 9 is electrically connected to the soft starter 3, the switch-control circuit 32 is configured to output, via the control terminal, a control signal to the switch 31 after a period of latency to control the switch 31 to switch from the open state to the closed state, such that the switch 31 allows the driving current to flow through the switch 31 to the one of the optical modules 9 for starting the one of the optical modules 9. The connection signal is related to an electrical state of connection between the power conversion circuit 1 and the one of the optical modules 9. It should be noted that in this embodiment, the control signal is a voltage signal, but may be a current signal in other embodiments.

In this embodiment, the switch 31 is implemented to be a metal-oxide-semiconductor field-effect transistor (MOSFET) that has a gate electrically connected to the control terminal of the switch-control circuit 32, a source adapted to be electrically connected to the power conversion circuit 1, and a drain adapted to be electrically connected to one of the optical modules 9. In one embodiment, the switch 31 is a p-channel MOSFET (PMOS). When the control signal changes from a high voltage level (e.g., 3.3 V) to a low voltage level (e.g., 0 V), the switch 31 switches from the open state to the closed state. In one embodiment, the switch 31 is an n-channel MOSFET (NMOS). When the control signal changes from the low voltage level to the high voltage level, the switch 31 switches from the open state to the closed state. However, implementation of the switch 31 is not limited to the disclosure herein and may vary in other embodiments. For example, the switch 31 may be also implemented by a bipolar junction transistor (BJT) or a similar active component. In one embodiment, the control signal is implemented to be a command that is a voltage series composed of specific voltage levels across time, and the switch 31 is implemented to be a circuit chip that switches to one of the open state and the closed state in response to the command.

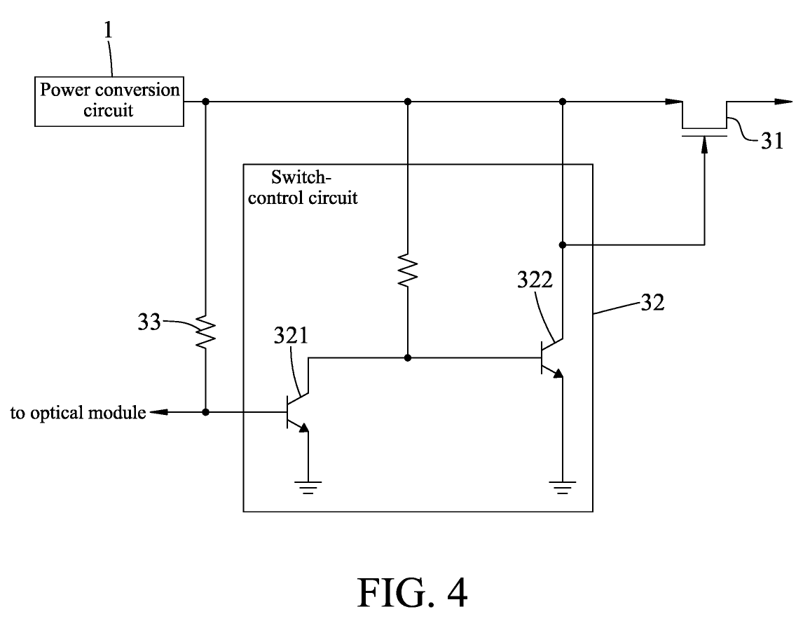

Referring to FIG. 4, the switch-control circuit 32 includes a first transistor 321 and a second transistor 322. The first transistor 321 has a base that is electrically connected to the first terminal of the switch-control circuit 32, an emitter that is grounded, and a collector. The first transistor 321 is configured to operate in one of a conduction state and a non-conduction state. The second transistor 322 has a base that is electrically connected to the collector of the first transistor 321, a collector that is electrically connected to the gate of the switch 31 (i.e., the control terminal of the switch 31), and an emitter that is grounded. The second transistor 322 is configured to operate in one of a conduction state and a non-conduction state. As shown in FIG. 4, a resistor is connected between the collector of the second transistor 322 and a common node of the collector of the first transistor 321 and the base of the second transistor 322. When one of the optical modules 9 is electrically connected to the soft starter 3, the connection signal changes to a low signal level (which may be a low voltage level or a low current level), which sequentially makes the first transistor 321 operate in the non-conduction state, the second transistor 322 operate in the conduction state, and the switch 31 operate in the closed state. In this embodiment, each of the first transistor 321 and the second transistor 322 is implemented by a BJT, but is not limited thereto. In other embodiments, each of the first transistor 321 and the second transistor 322 may be implemented by a MOSFET, a combination of MOSFET and BJT, or any equivalent circuit component. It is worthy of note that the period of latency mentioned previously arises from a reaction time allowing for the first transistor 321 to change from the conduction state to the non-conduction state and a reaction time allowing for the second transistor 322 to change from the non-conduction state to the conduction state.

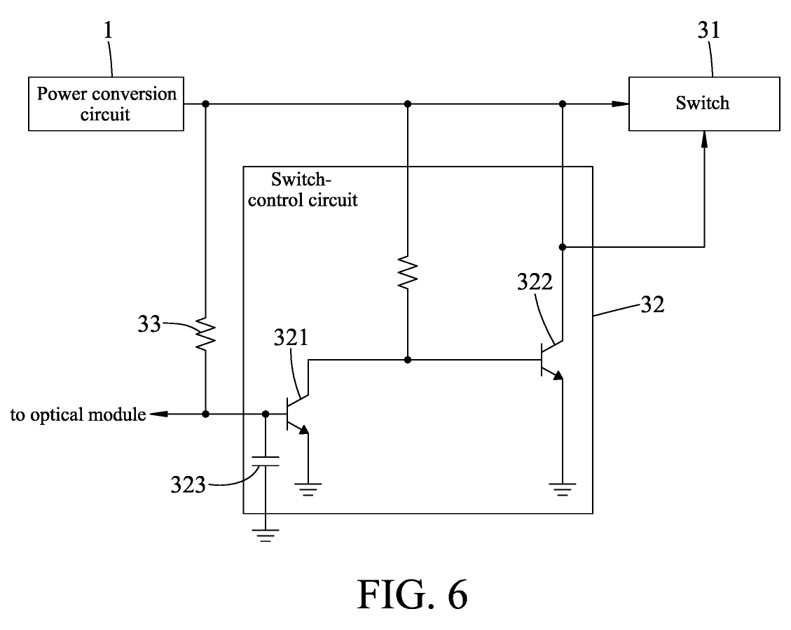

Referring to FIG. 6, in one embodiment, the switch-control circuit 32 further includes a first capacitor 323 that is electrically connected between the base of the first transistor 321 and ground. By virtue of properties of a capacitor, the reaction time allowing for the first transistor 321 to change from the conduction state to the non-conduction state can be adjusted.

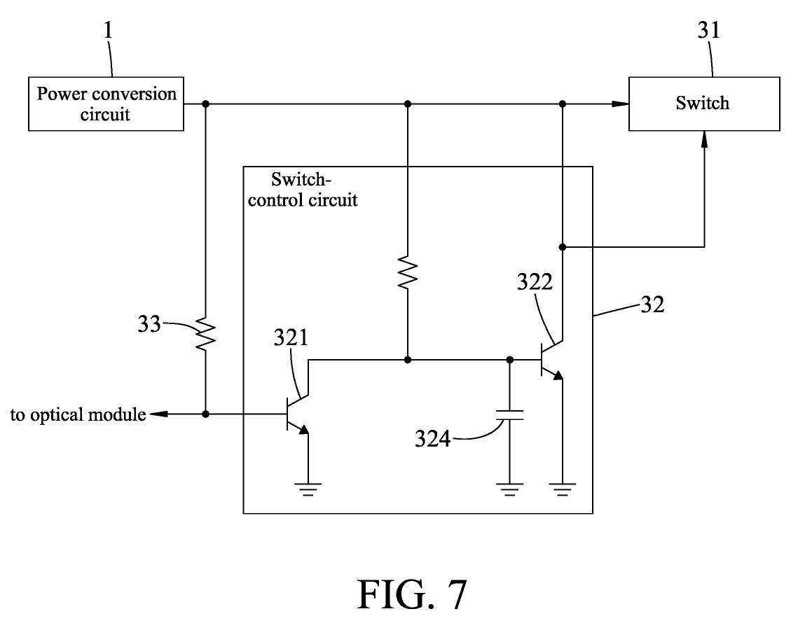

Referring to FIG. 7, in one embodiment, the switch-control circuit 32 further includes a second capacitor 324 that is electrically connected between the base of the second transistor 322 and ground. By virtue of properties of a capacitor, the reaction time allowing for the second transistor 322 to change from the non-conduction state to the conduction state can be adjusted.

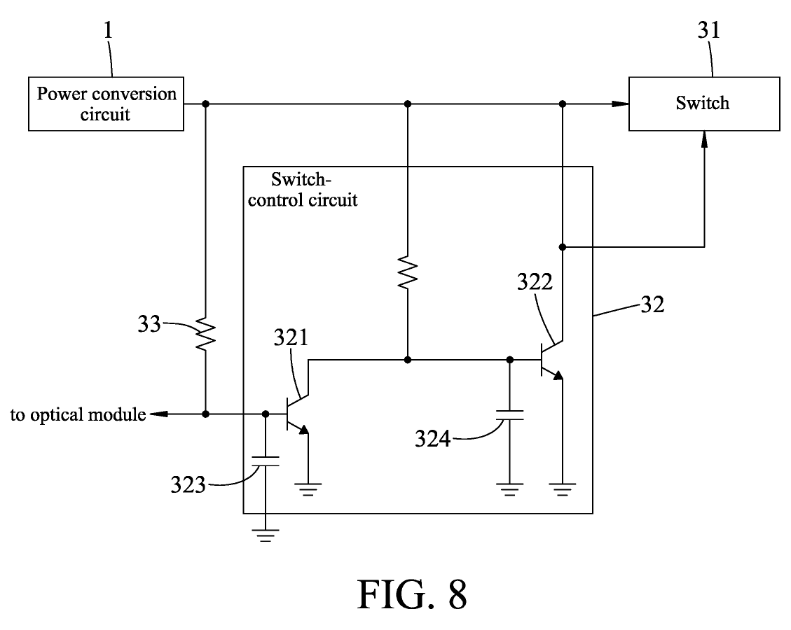

Referring to FIG. 8, in one embodiment, the switch-control circuit 32 further includes the first capacitor 323 that is electrically connected between the base of the first transistor 321 and ground, and the second capacitor 324 that is electrically connected between the base of the second transistor 322 and ground. By virtue of properties of a capacitor, the reaction time allowing for the first transistor 321 to change from the conduction state to the non-conduction state and the reaction time allowing for the second transistor 322 to change from the non-conduction state to the conduction state can be both adjusted. It should be noted that the first capacitor 323 and the second capacitor 324 may be identical or different, and capacitance of each of the first capacitor 323 and the second capacitor 324 can be adjusted according to resistance encountered by said each of the first capacitor 323 and the second capacitor 324 and practical needs of the aforesaid reaction times.

The pull-up resistor 33 is electrically connected between the power conversion circuit 1 and the first terminal of the switch-control circuit 32. The pull-up resistor 33 is configured to pull up a voltage level of the first terminal of the switch-control circuit 32 to a high voltage level (e.g., about 3.3 V).

The detecting circuit 34 is electrically connected to the switch 31, and the second terminal of the switch-control circuit 32, and is adapted to be electrically connected to one of the optical modules 9. The detecting circuit 34 is configured to receive a first reference voltage that is related to a power level of the one of the optical modules 9, and to generate, based on the driving current flowing through the switch 31, a second reference voltage that indicates a current intensity of the driving current currently outputted to the one of the optical modules 9. The detecting circuit 34 is further configured to generate, based on the first reference voltage and the second reference voltage, a comparison signal that indicates whether or not the driving current outputted to the one of the optical modules 9 is abnormal, and to send the comparison signal to the second terminal of the switch-control circuit 32. The switch-control circuit 32 is configured to, in response to receiving the comparison signal indicating that the driving current is abnormal, control the switch 31 to switch from the closed state to the open state.

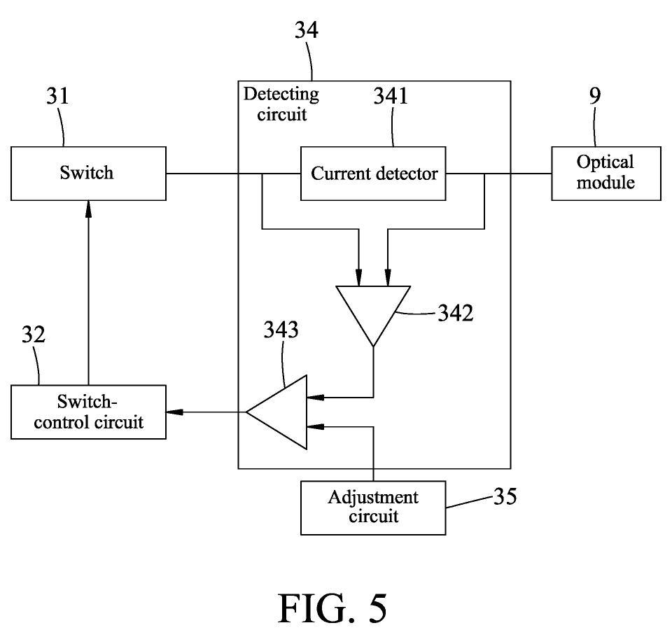

Specifically, referring to FIG. 5, the detecting circuit 34 includes a current detector 341, a first comparator 342 and a second comparator 343. The current detector 341 is electrically connected between the switch 31 and the one of the optical modules 9. The current detector 341 is configured to measure the current intensity of the driving current, and to generate the second reference voltage based on a result of measurement made by the current detector 341. In this embodiment, the current detector 341 is implemented to be a resistor that has two ends electrically connected respectively to the switch 31 and the one of the optical modules 9, but is not limited thereto. The first comparator 342 has an output terminal, and two input terminals electrically connected respectively to the two ends of the current detector 341. The first comparator 342 is configured to generate and output the second reference voltage via the output terminal based on a voltage different between the two ends of the current detector 341. The second comparator 343 has a first input terminal electrically connected to the output terminal of the first comparator 342 for receiving the second reference voltage from the first comparator 342, a second input terminal for receiving the first reference voltage, and an output terminal electrically connected to the second terminal of the switch-control circuit 32. The second comparator 343 is configured to generate the comparison signal based on the first reference voltage and the second reference voltage, and to output the comparison signal via the output terminal to the switch-control circuit 32. For example, when one of the optical modules 9 inserts into one of the ports 2 and receives the driving current from the power conversion circuit 1, the detecting circuit 34 of one of the soft starters 3 that is electrically connected between the power conversion circuit 1 and the one of the optical modules 9 would continuously generate the comparison signal based on the first reference voltage and the second reference voltage. When the driving current is normal, the second reference voltage is not greater than the first reference voltage. On the other hand, when the driving current is abnormal, the second reference voltage is greater than the first reference voltage. Thus, the comparison signal generated based on a difference between the first reference voltage and the second reference voltage is capable of indicating whether or not the driving current is abnormal. In a scenario where an unintended short circuit occurs within one of the optical modules 9 (hereinafter also referred to as the abnormal module) and causes an extremely high current, in response to receipt of the comparison signal indicating that the driving current is abnormal, the switch-control circuit 32 of one of the soft starters 3 (hereinafter also referred to as the corresponding starter) that is electrically connected to the abnormal module would control the switch 31 of the corresponding starter to operate in the open state, thereby cutting off the driving current flowing to the abnormal module.

As shown in FIG. 5, the adjustment circuit 35 is electrically connected to the second input terminal of the second comparator 343 of the detecting circuit 34. The adjustment circuit 35 is configured to receive system settings from the system mainboard 10, to generate the first reference voltage based on the system settings thus received, and to send the first reference voltage to the second comparator 343. It is worthy of note that the system settings is generated by the system mainboard 10 based on the specification information obtained by one of the ports 2 into which one of the optical modules 9 inserts. In this embodiment, the adjustment circuit 35 is a non-inverting adder that is implemented by using operational amplifiers, and voltages respectively of input pins of the non-inverting adder are configured based on the system settings. In other embodiments, the adjustment circuit 35 may be implemented to be a digital-to-analog converter (DAC). However, implementation of the adjustment circuit 35 is not limited to the disclosure herein and may vary in other embodiments.

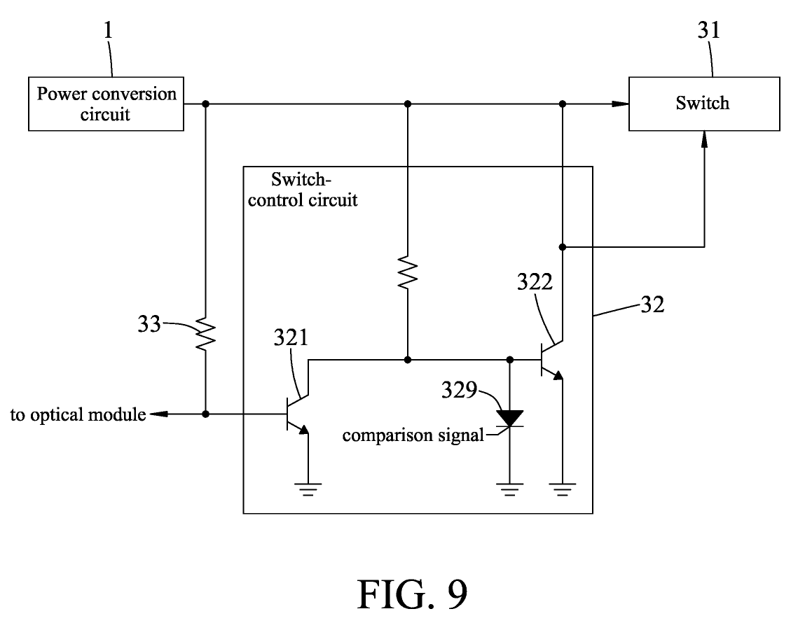

In one embodiment, the switch-control circuit 32 further includes a thyristor 329 as shown in FIG. 9. The thyristor 329 is electrically connected between the base of the second transistor 322 and ground. The thyristor 329 has a gate for receiving the comparison signal, and is configured to, in response to receiving the comparison signal indicating that the driving current is abnormal, operate in a conduction state to sequentially make the second transistor 322 operate in the non-conduction state and the switch 31 operate in the open state.

In one embodiment, for saving energy, the system mainboard 10 is configured to, in response to a user operation, operate in a sleep mode to reduce power consumption.

In one embodiment, when one of the optical modules 9 serves as a standby (hereinafter also referred to as the standby module) and is not ready to function, the system mainboard 10 is configured to enable the switch-control circuit 32 of one of the soft starters 3 (hereinafter also referred to as the standby starter) electrically connected to the standby module to control the switch 31 of the standby starter to operate in the open state, thereby cutting off the driving current flowing to the standby module and lowering power consumption of the system mainboard 10. The system mainboard 10 is configured to enable the switch-control circuit 32 of the standby starter to control the switch 31 of the standby starter to operate in the closed state when the standby module is ready to function.

To sum up, for the soft starter and the system mainboard 10 according to the disclosure, when the optical module 9 is electrically connected to the soft starter 3, the switch-control circuit 32 of the soft starter 3 controls, after a period of latency, the switch 31 of the soft starter 3 to switch from the open state to the closed state, so as to relieve an inrush current that arises in the driving current flowing through the switch 31 to the optical module 9. Consequently, damages of the optical module 9 caused by the inrush current may be prevented, thereby extending service life of the optical module 9. Moreover, when multiple optical modules 9 are electrically connected respectively to the soft starters 3 of the system mainboard 10, for each of the soft starters 3, the detecting circuit 34 is utilized to monitor the driving current, and to enable the switch-control circuit 32 to control the switch 31 to switch from the closed state to the open state when the driving current is abnormal. In this way, when one of the optical modules 9 malfunctions and causes abnormality in the driving current, impact of the abnormality in the driving current on others of the optical modules 9 and the power conversion circuit 1 may be alleviated.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A soft starter for an optical module, adapted to be electrically connected between a power conversion circuit and the optical module so as to transmit a driving current outputted by the power conversion circuit to the optical module, said soft starter comprising:
a switch adapted to be electrically connected between the power conversion circuit and the optical module, and configured to operate in one of a closed state for allowing the driving current to flow through said switch, and an open state for disallowing the driving current to flow through said switch; and
a switch-control circuit having a first terminal that is adapted to be electrically connected to the optical module, and a control terminal that is electrically connected to said switch, said switch-control circuit being configured to
detect, via said first terminal, a connection signal that indicates whether or not the optical module is electrically connected to said soft starter,
upon detecting the connection signal indicating that the optical module is electrically connected to said soft starter, output, via said control terminal, a control signal to said switch after a period of latency to control said switch to switch from the open state to the closed state, such that said switch allows the driving current to flow through said switch to the optical module for starting the optical module.

2. The soft starter as claimed in claim 1, wherein said switch is a metal-oxide-semiconductor field-effect transistor (MOSFET) that has a gate electrically connected to said control terminal of said switch-control circuit, a source adapted to be electrically connected to the power conversion circuit, and a drain adapted to be electrically connected to the optical module.

3. The soft starter as claimed in claim 2, wherein said switch-control circuit includes:
a first transistor having a base that is electrically connected to said first terminal of said switch-control circuit, an emitter that is grounded, and a collector, said first transistor being configured to operate in one of a conduction state and a non-conduction state; and
a second transistor having a base that is electrically connected to said collector of said first transistor, a collector that is electrically connected to said gate of said switch, and an emitter that is grounded, said second transistor being configured to operate in one of a conduction state and a non-conduction state,
wherein, when the optical module is electrically connected to said soft starter, the connection signal changes to a low signal level, which sequentially makes said first transistor operate in the non-conduction state, said second transistor operate in the conduction state, and said switch operate in the closed state.

4. The soft starter as claimed in claim 3, wherein said switch-control circuit further includes a capacitor that is electrically connected between said base of said first transistor and ground.

5. The soft starter as claimed in claim 3, wherein said switch-control circuit further includes a capacitor that is electrically connected between said base of said second transistor and ground.

6. The soft starter as claimed in claim 1, further comprising a detecting circuit electrically connected to said switch, wherein:
said switch-control circuit further has a second terminal that is electrically connected to said detecting circuit;
said detecting circuit is configured to
receive a first reference voltage that is related to a power level of the optical module,
generate a second reference voltage that indicates a current intensity of the driving current currently outputted to the optical module,
generate, based on the first reference voltage and the second reference voltage, a comparison signal that indicates whether or not the driving current outputted to the optical module is abnormal, and
send the comparison signal to said second terminal of said switch-control circuit; and
said switch-control circuit is configured to, in response to receiving the comparison signal indicating that the driving current is abnormal, control said switch to switch from the closed state to the open state.

7. The soft starter as claimed in claim 6, wherein:
said detecting circuit includes a current detector that is electrically connected between said switch and the optical module and that is configured to measure the current intensity of the driving current; and
said detecting circuit is configured to generate the second reference voltage based on a result of measurement made by said current detector.

8. The soft starter as claimed in claim 7, wherein:
said current detector is a resistor that has two ends electrically connected respectively to said switch and the optical module; and
said detecting circuit further includes
a first comparator that has two input terminals electrically connected respectively to said two ends of said current detector, and an output terminal, and that is configured to generate and output the second reference voltage via said output terminal based on a voltage different between said two ends of said current detector, and
a second comparator that has a first input terminal electrically connected to said output terminal of said first comparator for receiving the second reference voltage from said first comparator, a second input terminal for receiving the first reference voltage, and an output terminal electrically connected to said second terminal of said switch-control circuit, said second comparator being configured to generate the comparison signal based on the first reference voltage and the second reference voltage, and to output the comparison signal via said output terminal to said switch-control circuit.

9. The soft starter as claimed in claim 6, wherein said switch is a metal-oxide-semiconductor field-effect transistor (MOSFET) that has a gate electrically connected to said control terminal of said switch-control circuit, a source adapted to be electrically connected to the power conversion circuit, and a drain adapted to be electrically connected to the optical module.

10. The soft starter as claimed in claim 9, wherein said switch-control circuit includes:
a first transistor having a base that is electrically connected to said first terminal of said switch-control circuit, an emitter that is grounded, and a collector, said first transistor being configured to operate in one of a conduction state and a non-conduction state; and
a second transistor having a base that is electrically connected to said collector of said first transistor, a collector that is electrically connected to said gate of said switch, and an emitter that is grounded, said second transistor being configured to operate in one of a conduction state and a non-conduction state,
wherein, when the optical module is electrically connected to said soft starter, the connection signal changes to a low signal level, which sequentially makes said first transistor operate in the non-conduction state, said second transistor operate in the conduction state, and said switch operate in the closed state.

11. The soft starter as claimed in claim 10, wherein said switch-control circuit further includes a thyristor that is electrically connected between said base of said second transistor and ground, that has a gate for receiving the comparison signal, and that is configured to, in response to receiving the comparison signal indicating that the driving current is abnormal, operate in a conduction state to sequentially make said second transistor operate in the non-conduction state and said switch operate in the open state.

12. A system mainboard with a soft-start function, adapted to be electrically connected to at least one optical module, said system mainboard comprising:
a plurality of ports each being configured to allow one of said at least one optical module to insert thereinto;
a plurality of said soft starters of claim 1 respectively disposed in said plurality of ports; and
a power conversion circuit electrically connected to said plurality of said soft starters, and configured to, when one of said at least one optical module is inserted into one of said plurality of ports and is electrically connected to the corresponding one of said plurality of said soft starters, output a driving current to said one of said at least one optical module.

13. The system mainboard as claimed in claim 12, wherein for each of said plurality of said soft starters:
said soft starters further includes a detecting circuit electrically connected to said switch of said each of said plurality of said soft starters;
said switch-control circuit further has a second terminal that is electrically connected to said detecting circuit;
said detecting circuit is configured to
receive a first reference voltage that is related to a power level of the optical module,
generate a second reference voltage that indicates a current intensity of the driving current currently outputted to the optical module,
generate, based on the first reference voltage and the second reference voltage, a comparison signal that indicates whether or not the driving current outputted to the optical module is abnormal, and
send the comparison signal to said second terminal of said switch-control circuit; and
said switch-control circuit is configured to, in response to receiving the comparison signal indicating that the driving current is abnormal, control said switch to switch from the closed state to the open state.

14. The system mainboard as claimed in claim 13, wherein for each of said plurality of said soft starters:
said detecting circuit includes a current detector that is electrically connected between said switch and the optical module and that is configured to measure the current intensity of the driving current; and
said detecting circuit is configured to generate the second reference voltage based on a result of measurement made by said current detector.
